(19) United States
(12) Patent Application Publication
(10) Pub. No.: US 2005/0005956 A1
(43) Pub. Date: Jan. 13, 2005

(54) Fluorine gas treatment of washing machine parts

(75) Inventors: Christopher L. Flowers, Humboldt, TN (US); William Paul Rushing II, Medina, TN (US); Seungwon (Chris) Song, Jackson, TN (US)

Correspondence Address: DIEDERIKS & WHITELAW, PLC, 12471 Dillingham Square, #301, Woodbridge, VA, 22192, US

(73) Assignee: Maytag Corporation

(21) Appl. No.: 10/617,376

(22) Filed: Jul. 11, 2003

(51) Int. Cl. B08B 3/00; C23C 16/08

(52) U.S. Cl. 134/200; 427/248.1; 427/255.39

(57) ABSTRACT

Plastic components exposed to a washing chamber of a washing machine are treated with a fluorine-containing gas mixture for improving the stain resistance and drying performance of the plastic components. In accordance with the invention, a plastic component is placed in a reaction chamber and exposed to a gas mixture containing fluorine and oxygen for a sufficient amount of time for the gas mixture to react with the plastic component such that the gas mixture modifies at least a surface layer, thereby enhancing the resistance of the plastic component to staining, while improving drying performance characteristics. Plastic dishwasher components that may be treated by the gas mixture include a dishwasher tub, a door liner, spray arms, racks, silverware baskets, a pump housing, and the like. Washing tubs, agitators, baffles and the like of clothes washing machine could also be advantageously treated.

### BACKGROUND OF THE INVENTION

1. Field of the Invention

The present invention pertains to the art of washing machines, specifically dishwashers and clothes washing machines, and, more particularly, to plastic washing machine parts having improved resistance to stains and a method of treating the plastic parts to improve stain resistance.

2. Discussion of the Prior Art

Typically, interior walls of a dishwasher tub are formed of plastic, generally polypropylene. In addition, the use of plastic for the internal components of dishwashers, such as spray arms, is becoming increasingly popular due to the relatively low cost, lightweight, and flexibility of design offered by plastic. However, plastic dishwasher parts, as well as plastic food containers, are prone to staining by food residue. Plastic dishwasher parts are particularly prone to red stains from processed tomato products, such as tomato sauce, ketchup, and spaghetti sauce. Red stains, technically known as carotenoid stains, are caused by lycopene in tomato products. Lycopene can be absorbed into plastic items and cannot be completely removed by dishwashing detergents.

Although reducing the ability of a part to be stained may be of interest in certain other fields, the problems associated with staining are of particular concern in connection with plastic dishwasher components. For instance, both a tub and door liner of a dishwasher are typically white in color. During use, if these components are discolored by tomato or other food product stains, the overall appearance of the dishwasher is degraded. Certainly, consumers do not want to put dishes to be cleaned in a dishwasher which has a soiled or otherwise stained washing chamber. As plates or bowls containing tomato or other high staining foods are oftentimes not rinsed prior to loading a dishwasher, the staining foods will tend to drip onto the inner components of the dishwasher. If these staining foods remain on the plastic components for any significant length of time prior to operating the dishwasher, a certain amount of staining is sure to occur. Of course, many of the dishwasher parts could be made from materials which would inherently resist staining, such as stainless steel. However, although a market exists for such high-end products, the need to provide a more economically feasible dishwasher leads to the increasing need to employ plastic parts. Some similar problems also exist in connection with clothes washing machines, specifically those incorporating plastic washing tubs or spinners, agitators and/or baffles. Certainly, unsightly stains on these components will lead to customer dissatisfaction. Based on the above, there exists a need to make dishwasher parts from plastic that are more resistant to staining.

### SUMMARY OF THE INVENTION

The present invention is concerned with treating plastic components of a washing chamber with a fluorine-containing gas mixture in order to improve the stain resistance of plastic components. In accordance with the invention, the plastic components are placed in a reaction chamber into which a gas mixture containing fluorine and oxygen is introduced. The components and gas mixture remain in the chamber for a sufficient amount of time for the gas mixture to react with the plastic components, such that the gas mixture modifies at least a surface layer of the plastic components.

It has been found that treating washing machine components in this manner significantly alters the resistance of the plastic components to staining, even staining associated with tomato based products, which is of particular concern in the art of dishwashers. In connection with the invention, plastic dishwasher components that may be treated by the gas mixture include: dishwasher tubs, door liners, spray arms, racks, conduits, silverware baskets, pump housings, and the like. For clothes washing machines, plastic tubs or spinners, agitators, baffles and the like can be advantageously treated. That is, any plastic component which is arranged in a washing chamber so as to be subject to staining by foods or soiled clothes may be treated in accordance with the present invention.

Additional objects, features and advantages of the present invention will become more readily apparent from the following detailed description of preferred embodiments of the invention.

### BRIEF DESCRIPTION OF THE DRAWINGS

FIG. 1 is a view of a dishwasher containing plastic parts treated in accordance with the present invention;

FIG. 2 is a side view of a plastic dishwasher part treated in accordance with the invention; and

FIG. 3 is schematic representation of a treatment system employed in connection with the invention.

### DETAILED DESCRIPTION OF THE PREFERRED EMBODIMENTS

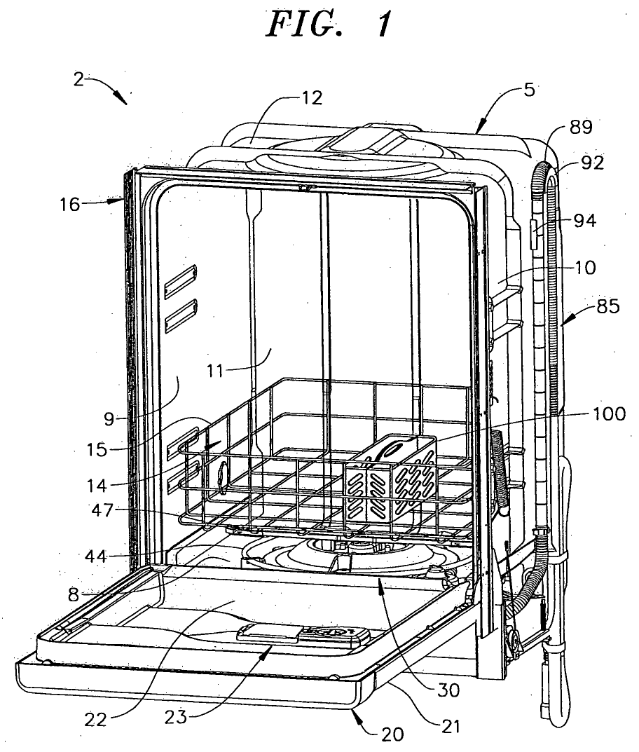

With initial reference to FIG. 1, the invention will be described with particular reference to a dishwasher 2. As shown, dishwasher 2 includes a tub 5, which is injection molded of plastic, preferably polypropylene, so as to include integral bottom, side, rear and top walls 8-12 respectively. Within the confines of walls 8-12, tub 5 defines a washing chamber 14 within which soiled kitchenware is adapted to be placed upon shiftable upper and lower racks (one of which is indicated at 15), with the kitchenware being cleaned during a washing operation in a manner widely known in the art. Tub 5 has attached thereto a frontal frame 16 which pivotally supports a door 20, having an outer panel 21 and an inner liner 22, used to seal chamber 14 during a washing operation. In connection with the washing operation, door 20 is preferably provided with a detergent tray assembly 23 within which a consumer can place liquid or particulate washing detergent for dispensing at predetermined cycles of the washing operation. Of course, dispensing detergent in this fashion is known in the art such that this arrangement is only being described for the sake of completeness.

Disposed within tub 5 and, more specifically, mounted within a central opening formed in bottom wall 8 of tub 5, is a pump and filter assembly 30. Extending about a substantial portion of pump and filter assembly 30, at a position raised above bottom wall 8, is a heating element 44. In a manner known in the art, heating element 44 preferably takes the form of a sheathed, electric resistance-type heating element.

In general, pump and filter assembly 30 is adapted to direct washing fluid to a lower wash arm 47 and an upper wash arm (not shown). Dishwasher 2 has associated therewith a drain hose 85 including at least one corrugated or otherwise curved portion 89 that extends about an arcuate hanger 92 provided on an outside surface of side wall 10. Drain hose 85 is also preferably secured to tub 5 through various clips, such as that indicated at 94. In any event, in this manner, an upper loop is maintained in drain hose 85 to assure proper drainage in a manner known in the art. Actually, a detailed description of the exact structure and operation of pump and filter assembly 30 of dishwasher 2 does not form part of the present invention, but is rather set forth in pending U.S. application Ser. No. 10/186,739 entitled “Dishwasher Pump and Filtration System” filed Jul. 2, 2002, incorporated herein by reference. In addition, a silverware basket 100 is shown positioned in rack 15 in a manner known in the art.

The present invention is actually directed to providing various components of dishwasher 2 with an increased resistance to stains. In general, the process includes exposing the dishwasher parts to a fluorine-containing gas mixture for an amount of time sufficient to allow the gas mixture to react with the plastic parts. The reaction that takes place between the plastic parts and the gas mixture modifies the surface of the plastic parts such that the parts exhibit the increased resistance to stains.

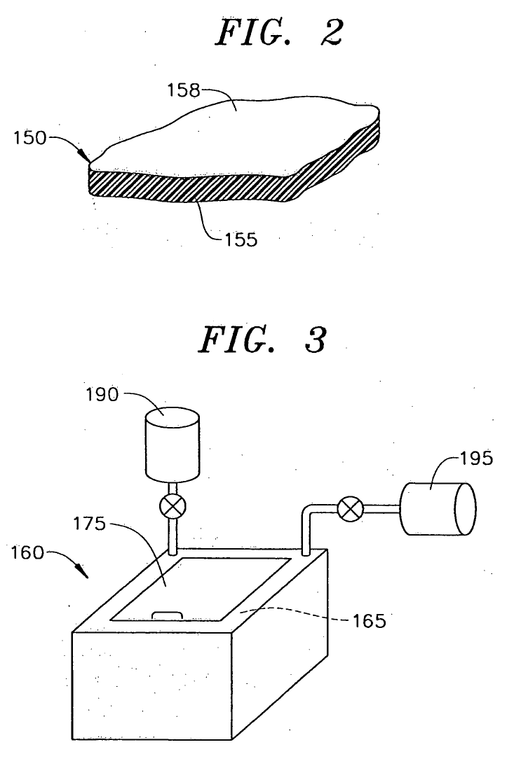

Essentially, any plastic dishwasher part that is susceptible to stains from contact with food residue may be treated by the process of the invention. The plastic dishwasher parts that may be treated include, but are not limited to, walls 8-12, a shiftable upper rack (not shown), shiftable lower rack 15, inner liner 22 of door 20, dispensing assembly 23, lower wash arm 47, an upper wash arm (not shown), at least the housing for pump and filter assembly 30, basket 100, and the like. However, for discussion purposes, reference will be made to FIGS. 2 and 3 in discussing the treatment of a representative plastic dishwasher part which is generically referred to as plastic part 150. Preferably, plastic part 150 includes a main body 155 which is molded of polypropylene. Main body 155 has at least one surface 158 exposed to washing chamber 14.

The treatment in accordance with the invention includes placing plastic part 150 within a closed reaction chamber unit 160 having an internal reaction chamber 165 which can be selectively sealed by one or more doors 175. Reaction chamber 165 may be of any suitable size or shape to permit easy placement and removal of part 150. Further, reaction chamber 165 may be constructed from stainless steel or any suitable material known in the art. After placing part 150 into reaction chamber 165, the gas mixture is introduced into chamber 165 from a storage vessel 190. The gas mixture contains fluorine and may include other reactive gases, such as oxygen. Further, the gas mixture inevitably includes a quantity of inert gas, such as nitrogen. Preferably, fluorine makes up less than 10% of the gas mixture, with the remainder being a mixture of oxygen and nitrogen. In accordance with the most preferred embodiment of the invention, the reaction is carried out at a temperature of 30-70° C., most preferably about 45° C., and a pressure of 0.1-0.9 atm, most preferably about 0.5 atm.

Plastic part 150 remains in reaction chamber 165 for a sufficient amount of time for the fluorine and oxygen gases to react with at least an outer layer 158 of plastic part 150. More specifically, since part 150 is preferably formed of polypropylene, the fluorine and oxygen atoms from the gas mixture replace many of the hydrogen atoms located on outer layer 158 of the polypropylene part 150. Generally, the longer part 150 is exposed to the gas mixture in reaction chamber 165, the more hydrogen atoms will be replaced. Hence, longer exposure times lead to a greater depth of penetration of the reaction. Typically, surface 158 of plastic part 150 is sufficiently treated in 0.5-60 minutes. For example, walls 8-12 of chamber 14 are 90-120 mils in thickness. By placing walls 8-12 within reaction chamber 165 containing the gaseous mixture for 10-20 minutes, the reaction will have penetrated walls 8-12 to 2,000 angstroms.

Treatment with the gas mixture in accordance with the invention is considered to be advantageous over plasma, corona, or flame treatments because the changes of surface 158 in plastic part 150 that result from the treatment are permanent due to the depth of penetration of the reaction. Following the treatment of plastic part 150, any remaining treatment gas and by-product gases are evacuated from reaction chamber 165, such as into containment vessel 195. These gases may be discarded or, more preferably, recycled. Alternatively, the gases may be used in a scrubbing process. Following removal from reaction chamber 165, plastic part 150 may be installed into dishwasher 2 without undergoing any additional processing. The following examples are presented to further illustrate the present invention and are not meant to be limiting:

### EXAMPLE 1

Example 1 was carried out to measure the difference in the stain resistance of plastic dishwasher parts that have been treated with the gas mixture of the invention versus parts not treated with the gas mixture. An initial test was performed wherein two dishwashers were subjected to thirty wash cycles. Prior to the initial wash cycle, a meat and tomato sauce mixture was placed within the washing chamber of each dishwasher. More specifically, a standard soiling protocol test (ANSI/AHAM DW-1-1992) was modified by adding an additional 12 oz. can of tomato paste to the meat mixture. Additional amounts of the meat and tomato sauce mixture were added to the washing chambers between each wash cycle. No cleaning or other modification of the dishwashers took place between cycles. One dishwasher included plastic parts which had been treated in accordance with the present invention and the other dishwasher included identical plastic parts which were not treated. The change in color of the plastic parts was measured after thirty wash cycles. The change in color is indicated by ΔE, which is a single number that defines an elliptical color difference around the product standard. As shown in Table 1, the color of the untreated dishwasher parts had changed by 18.2 as compared to a change of only 5.8 in the plastic parts treated by the fluorine gas mixture.

TABLE 1
Color change (ΔE value*) after DW1 test.

| DW1 | w/o treatment | w/treatment |
|---|---|---|
| 30 cycles | 18.2 | 5.8 |

*ΔE: a single number which defines an elliptical color difference around the product standard.

In addition, a brightness parameter (Y) of the dishwasher parts was measured after ten, twenty, and thirty dishwasher cycles. The brightness parameter is a measure of luminance, which is light intensity factored by the sensitivity of a normal human eye. Starting with a brightness parameter of 100 prior to the initiation of the first wash cycle, the results are shown in Table 2. After ten wash cycles, the brightness parameter of the untreated parts was reduced to 71.6. After twenty wash cycles, the untreated parts again dulled to give a brightness parameter of 69.4. Following all thirty wash cycles, the brightness parameter of the untreated parts was 64.6. This is a decrease in brightness of 35.4 over thirty wash cycles. However, the brightness parameter of the parts treated by the fluorine gas mixture was 81.9, 80. 1, and 81.3 after ten, twenty and thirty wash cycles, respectively. Therefore, the total reduction in brightness of the treated parts was only 18.7 over thirty wash cycles, as compared to 35.4 for the untreated parts.

TABLE 2
Brightness parameter (Y value**) after DW1 test

| DW1 | w/o treatment | w/treatment |
|---|---|---|
| 10 cycles | 71.6 | 81.9 |
| 20 cycles | 69.8 | 80.1 |
| 30 cycles | 64.6 | 81.3 |

**The brightness parameter (Y) is a measure of luminance, which is light intensity factored by the sensitivity of the normal human eye.

### EXAMPLE 2

In a second test, four plastic test samples, i.e., one untreated sample and three treated samples, were placed in a dishwasher soiled with a tomato mixture to demonstrate the stain resistance of plastic parts treated by the gas mixture. Initially, a color reading was taken of the one untreated sample and three treated samples. The first treated sample was treated with a gas mixture having 5% fluorine, 5% oxygen and 90% nitrogen. The second treated sample was treated with a gas mixture having 1% fluorine, 5% oxygen and 94% nitrogen. The third treated sample was treated with a gas mixture having 2% fluorine, 3% oxygen and 95% nitrogen. Each of the samples was placed within a dishwasher rack or silverware basket inside the washing chamber. A two cup microwavable bowl was used to measure ¼ cup of a meat mixture and ½ cup of tomato sauce. A rubber spatula was used to scrape all of the tomato sauce out of a can. The mixture was then stirred and heated in a microwave for about two minutes before being poured onto the inner liner of the dishwasher door. In addition, the soiled bowl and spatula were placed within the dishwasher chamber. Two tablespoons of detergent were placed in the dispensing assembly and a normal wash cycle was performed. The procedure was performed a total of three times. Between each cycle and following the completion of all cycles, color readings were taken for each of the samples. The results are indicated in Table 3 below.

TABLE 3
Color change after tomato stain test

| | ΔL | Δa | Δb | ΔE* |
|---|---|---|---|---|
| PP - Untreated | | | | |
| Before the test | 3.11 | 0.30 | 0.88 | — |
| After 1^{st} Cycle | 6.25 | 9.99 | 9.50 | 13.34 |
| After 2^{nd} Cycle | 12.11 | 14.91 | 15.44 | 22.50 |
| After 3^{rd} Cycle | 7.30 | 12.35 | 26.44 | 24.00 |
| Sample 1 | | | | |
| Before the test | 4.24 | 0.33 | 0.23 | — |
| After 1^{st} Cycle | 4.75 | 1.00 | 0.55 | 0.90 |
| After 2^{nd} Cycle | 4.88 | 0.81 | 0.34 | 0.93 |
| After 3^{rd} Cycle | 4.86 | 0.62 | 0.55 | 0.72 |
| Sample 2 | | | | |
| Before the test | 5.25 | 0.19 | 1.79 | — |
| After 1^{st} Cycle | 5.06 | 0.99 | 0.25 | 1.75 |
| After 2^{nd} Cycle | 4.90 | 0.72 | 0.74 | 1.22 |
| After 3^{rd} Cycle | 4.81 | 0.69 | 1.32 | 0.81 |
| Sample 3 | | | | |
| Before the test | 4.32 | 0.23 | 0.88 | — |
| After 1^{st} Cycle | 5.06 | 0.89 | 0.30 | 1.15 |
| After 2^{nd} Cycle | 4.80 | 0.67 | 0.79 | 0.66 |
| After 3^{rd} Cycle | 4.68 | 0.72 | 1.50 | 0.87 |

ΔL: The change in lightness between treated sample after specified cycle and sample before test.
Δa: The change in red/green tones between treated sample after specified cycle and sample before test.
Δb: The change in yellow/blue tones between treated sample after specified cycle and sample before test.
ΔE*: The total color difference between treated sample after specified cycle and sample before test.

In table 3, the first column, ΔL, indicates a change in lightness in the samples before testing began and after the first, second and third wash cycles. The second column, Δa, indicates a change in red/green tones in the samples before testing began and after the first, second and third wash cycles. The third column, Δb, indicates a change in yellow/blue tones in the samples before testing began and after the first, second and third wash cycles. The last column, ΔE*, indicates the total color difference in the samples before testing began and after the first, second and third wash cycles. For example, the color of the untreated sample changed by 13.34 after the first cycle. After the second cycle, the color of the untreated sample had changed by a total of 22.50 and, after the third cycle, by a total of 24.00. This is a very significant change in color when compared to the changes in the treated samples, particularly the first treated sample which experienced color reading changes of 0.90, 0.93 and 0.72 after the first, second and third cycles, respectively.

In addition to the stain resistance aspects of the invention, the treated plastic machine components have been found to not develop carotenoid stains caused by foods that contain lycopene. The surfaces of the components also exhibit improved surface energy or wettability, as well as enhanced drying characteristics as water tends to spread out on the components instead of beading into large droplets. In any case, it should be readily apparent that treating plastic dishwasher components in accordance with the invention makes the components significantly more resistant to being stained from even the worst types of staining food substances typically experienced in connection with a domestic dishwasher. For a relatively minor incremental cost, various dishwasher components can be treated to provide a long-lasting, more aesthetically appealing and overall hygienic washing chamber arrangement. In any case, although described with reference to a preferred embodiment of the invention, it should be readily understood that various changes and/or modifications can be made to the invention without departing from the spirit thereof. For instance, although the invention is seen to have particular use in connection with treating dishwasher components, other washing machine components can benefit from the invention for generally corresponding reasons. For example, clothes washing machine tubs or spinners can be made of plastic, as well as agitators and baffles located in the tubs. Treating these washing machine components in a corresponding manner can prevent staining from various soils removed from clothing, as well as dyes which are inherently drawn from certain clothing during washing operations. In general, the invention is only intended to be limited by the scope of the following claims.

1. A method for improving stain resistance of a plastic washing machine component comprising:
placing the plastic washing machine component in a reaction chamber;
introducing a gas mixture containing fluorine and oxygen into the reaction chamber; and
reacting the gas mixture with the plastic washing machine component within the reaction chamber until the gas mixture modifies at least a surface layer of the plastic washing machine component to make the plastic washing machine component more resistant to staining.

2. The method according to claim 1, wherein the plastic washing machine component is molded of polypropylene.

3. The method according to claim 1, further comprising: retaining the plastic component in the reaction chamber with the gas mixture for about 0.5-60 minutes.

4. The method according to claim 1, further comprising: establishing a fluorine content at less than 10% of the gas mixture, by volume.

5. The method according to claim 4, further comprising: establishing a fluorine content less than or equal to 5% of the gas mixture, by volume.

6. The method according to claim 1, further comprising: providing nitrogen in the gas mixture.

7. The method according to claim 1, further comprising: penetrating the plastic component with the gas mixture to about 1000 angstroms.

8. The method according to claim 1, further comprising: utilizing the plastic washing machine component to form a dishwasher.

9. The method according to claim 8, further comprising: employing a dishwasher tub as the plastic washing machine component.

10. The method according to claim 8, further comprising: employing a dishwasher door liner as the plastic washing machine component.

11. The method according to claim 8, further comprising: employing a dishwasher spray arm as the plastic washing machine component.

12. The method according to claim 1, further comprising: maintaining the reaction chamber at a temperature of approximately 30-70° C.

13. The method according to claim 1, further comprising: establishing a pressure of approximately 0. 1-0.9 atmospheres in the reaction chamber.

14. A washing machine having internal components with improved resistance to stains comprising:
a first washing machine component defined by a tub;
a second washing machine component defined by a door movable between an open position, wherein access to within the tub is permitted, and a closed position, wherein a washing chamber is established by the tub and door; and
a third washing machine component arranged with the washing chamber, at least one of the first, second and third washing machine components being formed from a plastic material and having a surface, exposed to the washing chamber, which has been treated with a fluorine containing gas mixture such that the surface has been modified to enhance a resistance thereof to staining.

15. The washing machine according to claim 14, wherein the plastic material is polypropylene.

16. The washing machine according to claim 14, wherein the at least one of the first, second and third components constitutes the tub.

17. The washing machine according to claim 14, wherein the at least one of the first, second and third components constitutes an inner liner of the door.

18. The washing machine according to claim 14, wherein the at least one of the first, second and third components constitutes a dishwasher spray arm.

19. The washing machine according to claim 14, wherein the surface has been modified to a thickness of approximately 2000 angstroms.

20. The washing machine according to claim 14, wherein the surface of the at least one of the first, second and third components has also been modified to enhance characteristics of drying performance by being treated with the fluorine containing gas mixture.
